(19) United States
(12) Patent Application Publication
(10) Pub. No.: US 2016/0105146 A1
(43) Pub. Date: Apr. 14, 2016

(54) Input Power Capacity Detector embodying a method for measuring the maximum power (Pmax) available from a photo voltaic panel or array of photo voltaic panels without requirement that a connected AC powered device draws power at the time of measurement

(71) Applicant: Sergio Ammirata, Coral Springs, FL (US)

(72) Inventor: Sergio Ammirata, Coral Springs, FL (US)

(21) Appl. No.: 14/511,768

(22) Filed: Oct. 10, 2014

(51) Int. Cl. G01R 31/40; H02S 40/30; G01R 21/00

(52) U.S. Cl. CPC H02S 50/00; G01R 21/00; H02S 40/30

(57) ABSTRACT

A method of measuring the maximum power available from a photo voltaic array without the requirement of connected AC devices drawing power at time of measurement. Such a method allows for the design of systems which may prevent the unnecessary or potentially damaging startup of said AC devices at times at which power is not sufficient to power them safely. This is achieved by use of a power converter which converts the variable DC input voltage from the PV to a known, fixed DC voltage, then disabling the power converter at defined intervals for very short periods, taking a measurement of the Voc, when risen, and then shorting the current through a resistor and measuring Isc. Measurements are communicated to a central processing unit, which calculates Pmax.

### BACKGROUND AND PRIOR ART

Power derived from a photo voltaic panel or array of panels varies with the amount of sunlight, heat, and other factors. Knowing the amount of available power output and associated DC current and DC voltage from the array is vitally important for its efficient conversion by an inverter to AC current and AC voltage for use by AC powered devices. It is also important that the amount of converted power be sufficient for use by said AC devices. Current methods that optimize and measure the extracted power depend upon at least one connected device drawing AC power from the inverter. Such systems, therefore, have no ability to detect that power will be sufficient for (at minimum) the first device to connect and draw power. Most if not all systems automatically shut off power to the connected devices should available power be insufficient after the device has begun to draw power. Knowing the available power output before connecting the first AC power drawing device would provide an advantage in that said device need not be started before power is sufficient, preventing any unnecessary or potentially damaging startup.

Several factors determine the efficiency of a solar cell, including Pmax, the energy conversion efficiency, and the fill factor (FF). These points are illustrated in FIG. 1, which shows a typical forward bias I-V curve of an active PV cell. Pmax is the product of the maximum cell current (Imax) and voltage (Vmax) where the power output of the cell is greatest. Pmax is located at the “knee” of the curve.

The fill factor is a measure of how far the I-V characteristics of an actual PV cell differ from those of an ideal cell. The fill factor is defined as:

$$FF = \frac{Imax \times Vmax}{Isc \times Voc}$$

where:
Imax=the current at the maximum power output
Vmax=the voltage at the maximum power output
Isc=the short-circuit current
Voc=the open-circuit voltage

Because Pmax=Imax×Vmax, we can calculate the value of Pmax by using the formula:

Pₘₐₓ=FF×V_{oc}×I_{sc}

Methods to regulate some of the characteristics of a photo voltaic panel generator during the power extraction phase include measuring the short circuit current using small pulses and a reference generator (Mieth et al, 1987, U.S. Pat. No. 4,695,785A). That method does not measure the open circuit voltage. The novelty of the design in this submission is that by measuring both short circuit current and open circuit voltage, it allows for the precise calculation of the available power and enables measurement at shorter intervals. The prior art patent also uses a boost converter whereas this design can use a buck, boost or buck-boost converter. An additional requirement of the prior art patent is that the measurement take place during the extraction of power to connected AC devices and this design measures regardless of whether power is being extracted by said devices or not.

There is also very well defined method in the industry for extracting the optimal amount of energy Pmax from a photo voltaic panel generator. This method is called MPP (Maximum Power Point), and the process for tracking it in real time is called MPPT (Maximum Power Point Tracking). It involves performing real time measurements of the voltage and current being extracted from a photo voltaic panel (Decker et al, U.S. Pat. No. 560,430, 1997). MPPT measurement methods of “potential” max power differ from this design in that the measurement method is unavailable unless the connected devices actively draw power.

### ADVANTAGES

Knowledge of the measurement Pmax prior to extracting current is advantageous to PV systems applications supplying power to connected electrical devices because it permits design of systems which may prevent the unnecessary or potentially damaging startup of said connected electrical devices at times at which Pmax is not sufficient to power the devices safely.

### SUMMARY

In this invention we present a method for measuring Pmax in a PV generator at predefined discrete time intervals regardless of whether or not power is being extracted from said PV generator (FIG. 2). The method is embodied in a device (FIG. 3) which measures the open circuit voltage and short circuit current on the array at predefined intervals (2 s) using a very short measurement time window (2 ms in our prototype). This device is called an “Input Power Capacity Detector.”

### DRAWINGS

FIG. 1

FIG. 2

FIG. 3

FIG. 4

### REFERENCE NUMERALS

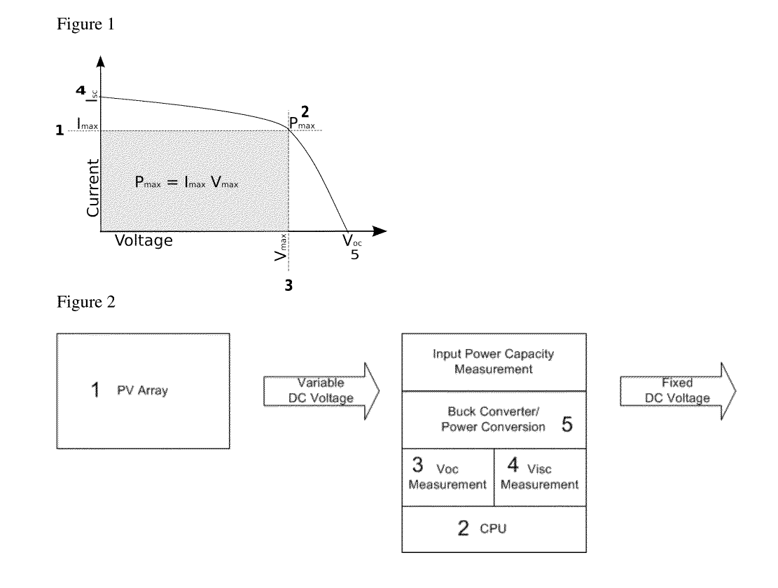

FIG. 1:

1. Imax=the current at the maximum power output
2. Pmax=the maximum power output
3. Vmax=the voltage at the maximum power output
4. Isc=the short-circuit current
5. Voc=the open-circuit voltage

FIG. 2:
1. PV Array
2. CPU
3. Voltage Detector: Voc Measurement
4. Voltage Detector: VIsc Measurement
5. Buck Converter

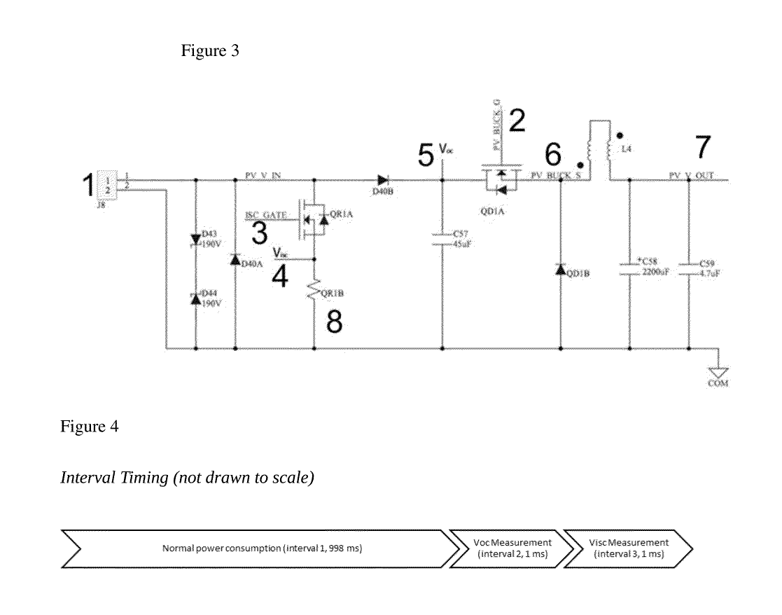

FIG. 3:
1. PV current input
2. Buck Converter Gate
3. Isc Gate
4. VIsc Measurement
5. Voc Measurement
6. Buck Converter
7. Regulated DC Voltage out
8. Resistor

FIG. 4:

No descriptions necessary.

### DETAILED DESCRIPTION AND OPERATION OF FIRST EMBODIMENT

FIG. 2 is a block diagram representing the Input Power Capacity Detector, as well as the PV source and CPU which analyzes the measurements made by the Input Power Capacity Detector. FIG. 3 is a circuit diagram of that part of the prototype Input Power Capacity Detector at which the measurement process takes place.

Incoming PV DC current enters the Input Power Capacity Detector at FIG. 3, numeral 1. Two switch gates, the buck gate and the Isc gate (FIG. 3, numerals 2 and 3), directed by a micro controller (see FIG. 2, numeral 2) open and close at three defined intervals (FIG. 4). The interval pattern is repeated cyclically without interruption between measurement cycles.

During the normal power consumption interval (interval 1; this interval is referred to as the normal power consumption interval regardless of whether a connected device draws power), current passes through a buck converter (FIG. 3, numeral 6), which down-converts the DC voltage to a known, regulated (lower) DC voltage (FIG. 3, numeral 7). During this interval (interval 1), the buck gate is closed and Isc gate is open. Note that this embodiment specifies a buck converter, but that a boost or buck-boost converter would work similarly.

During the Open Circuit Voltage (Voc) measurement interval (interval 2), both the buck gate and the Isc gate are open and no current circulates through the system. At the end of this interval, a measurement of the voltage Voc at FIG. 3, numeral 5 is taken by the Voltage Detector (FIG. 2 numerals 3 and 4).

Under the Short Circuit Current measurement interval (interval 3), the buck gate is open, the Isc gate is closed and current flows through the resistor (FIG. 3, Numeral 8). At the end of this interval, a measurement of the voltage VIsc at FIG. 3, numeral 4 is taken. The central processing unit then calculates the Isc using the formula Isc=VIsc/R where R is the resistance.

These measurements are then used by central processing unit to calculate Pmax using the formulae described in the Background section. The measurement process is repeated according to a schedule previously determined providing one measurement of available power per interval. This measurement of power can be used by the central processing unit to perform decisions related to other components of its larger ensemble or for logging purposes.

### CONCLUSION

The measurement of the available maximum power from a photo voltaic array, regardless of whether power is being extracted at the time of measurement, allows for the design of systems which may prevent the unnecessary or potentially damaging startup of connected electrical devices at times at which

Pmax is not sufficient to power the devices safely. This ability to calculate this measurement is not presently available unless power is being extracted at the time of measurement. This invention provides such a method of measurement.

1. A method for measuring the available maximum power from a photo voltaic panel or array of a known fill factor (as specified by its manufacturer), regardless of whether power is being ex-tracted at the time of measurement, comprising
a. A power converter which converts the variable DC input voltage from the PV to a known, fixed DC voltage. This power converter can be a buck converter, a boost converter or a buck-boost converter.
b. a 3 stage set of timer intervals
c. an input power switch/gate which, at predefined discrete time intervals marked by said interval timer, using a very short measurement-time window marked by said timer, dis-ables the power converter, allowing the voltage to rise to Voc
d. a Resistor of known resistance
e. an Isc switch/gate which when the power converter is disabled, at predefined discrete time intervals marked by said interval timer, using a very short measurement-time window marked by said timer, closes the circuit through a resistor of known resistance
f. a voltage detector which measures Voc at said intervals when the PV power switch is open and the Isc switch is open, and which communicates the measurement to a central processing unit
g. said voltage detector which measures VIsc, the voltage across the resistor of known resis-tance, at said intervals when the PV power switch is open and the Isc switch is closed, and which communicates the measurement to a central processing unit
h. said central processing unit, which calculates Isc from VIsc and the resistor of known value using the formula Isc=VIsc/R. Said central processing unit then calculates Pmax using the said measurements Voc, Isc, using the formula Pmax=FF×Voc×Isc where FF is the fill factor value provided by the manufacturer of the photo voltaic panels.
